(19) United States
(12) Patent Application Publication
(10) Pub. No.: US 2026/0122766 A1
(43) Pub. Date: Apr. 30, 2026

(54) PRINTED CIRCUIT BOARD AND METHOD OF MANUFACTURING PRINTED CIRCUIT BOARD

(71) Applicant: SUMITOMO ELECTRIC PRINTED CIRCUITS, INC., Shiga (JP)

(72) Inventors: Akihiro YANO, Shiga (JP); Yukinori NISHIMURA, Shiga (JP); Ayaka IZUMI, Shiga (JP)

(73) Assignee: SUMITOMO ELECTRIC PRINTED CIRCUITS, INC., Shiga (JP)

(21) Appl. No.: 19/368,518

(22) Filed: Oct. 24, 2025

(30) Foreign Application Priority Data
Oct. 28, 2024 (JP) 2024-188983

(51) Int. Cl. H05K 1/02; H05K 1/03

(52) U.S. Cl. CPC H05K 1/0218; H05K 1/0366

(57) ABSTRACT

A printed circuit board includes a first dielectric layer, a signal pattern, a first contact portion, a second dielectric layer, and a first ground pattern. The first dielectric layer has a first surface and a second surface. The signal pattern is arranged on the second surface and extends in a first direction. The first contact portion is arranged on the second surface and connected to one end of the signal pattern. The second dielectric layer is arranged on the second surface to cover the signal pattern and expose the first contact portion. The first ground pattern is arranged on the second dielectric layer. The second dielectric layer has an adhesion layer and a resin layer including a cloth in which a reinforced fiber is woven. The resin layer has a first side surface adjacent to the first contact portion in the first direction.

### CROSS REFERENCE TO RELATED APPLICATIONS

This application claims priority based on Japanese Patent Application No. 2024-188983 filed on October 28, 2024, and the entire contents of the Japanese patent application are incorporated herein by reference.

### TECHNICAL FIELD

The present disclosure relates to a printed circuit board and a method of manufacturing a printed circuit board.

### BACKGROUND

Japanese Unexamined Patent Application Publication No. 2011-54919 (Patent Literature 1) describes a printed circuit board. The printed circuit board described in Patent Literature 1 has a first ground pattern, a second ground pattern, and a signal pattern. The signal pattern is sandwiched between the first ground pattern and the second ground pattern. A dielectric layer is interposed between the signal pattern and the first ground pattern and between the signal pattern and the second ground pattern. That is, the signal transmission path of the printed circuit board described in Patent Literature 1 has a strip line structure.

[Patent Literature 1]: Japanese Unexamined Patent Application Publication No. 2011-54919

### SUMMARY

A printed circuit board according to the present disclosure includes a first dielectric layer, a signal pattern, a first contact portion, a second dielectric layer, and a first ground pattern. The first dielectric layer has a first surface and a second surface opposite to the first surface. The signal pattern is arranged on the second surface and extends in a first direction in plan view. The first contact portion is arranged on the second surface and connected to one end of the signal pattern in the first direction. The second dielectric layer is arranged on the second surface to cover the signal pattern and expose the first contact portion. The first ground pattern is arranged on the second dielectric layer. The second dielectric layer has an adhesion layer and a resin layer arranged on the adhesion layer and including a cloth in which a reinforced fiber is woven. The resin layer has a first side surface adjacent to the first contact portion in the first direction. The cloth is located further inward than the first side surface in the first direction.

### BRIEF DESCRIPTION OF THE DRAWINGS

FIG. 1 is a plan view of a printed circuit board 100.

FIG. 2 is a cross-sectional view taken along line II-II in FIG. 1.

FIG. 3 is a manufacturing flowchart of a printed circuit board 100.

FIG. 4 is a cross-sectional view explaining a preparing step S1.

FIG. 5 is a cross-sectional view explaining a preparing step S2.

FIG. 6 is a cross-sectional view explaining a dielectric-layer affixing step S3.

FIG. 7 is a cross-sectional view explaining a patterning step S4.

FIG. 8 is a cross-sectional view explaining a preparing step S2 in manufacturing steps of a printed circuit board 200.

FIG. 9 is a cross-sectional view of a printed circuit board 200.

FIG. 10 is a plan view of a printed circuit board 300.

FIG. 11 is a cross-sectional view taken along line XI-XI in FIG. 10.

FIG. 12 is a cross-sectional view of a printed circuit board 100 according to a modification.

### DETAILED DESCRIPTION

When the dielectric layer is made of a fluororesin, it is effective to arrange a cloth obtained by weaving a reinforced fiber in the dielectric layer in order to reduce the thermal expansion coefficient of the dielectric layer. The present disclosure provides a printed circuit board capable of suppressing a reinforced fiber from becoming a burr on a side surface of a dielectric layer covering a signal pattern.

### [Description of Embodiments of Present Disclosure]

First, embodiments of the present disclosure will be listed and described.

(1) A printed circuit board according to the present disclosure includes a first dielectric layer, a signal pattern, a first contact portion, a second dielectric layer, and a first ground pattern. The first dielectric layer has a first surface and a second surface opposite to the first surface. The signal pattern is arranged on the second surface and extends in a first direction in plan view. The first contact portion is arranged on the second surface and connected to one end of the signal pattern in the first direction. The second dielectric layer is arranged on the second surface to cover the signal pattern and expose the first contact portion. The first ground pattern is arranged on the second dielectric layer. The second dielectric layer has an adhesion layer and a resin layer arranged on the adhesion layer and including a cloth in which a reinforced fiber is woven. The resin layer has a first side surface adjacent to the first contact portion in the first direction. The cloth is located further inward than the first side surface in the first direction. According to the printed circuit board of the above (1), the reinforced fiber is suppressed from becoming a burr on the side surface of the second dielectric layer. Furthermore, according to the printed circuit board of the above (1), the transmission characteristics of the high frequency signal are improved.

(2) The printed circuit board of the above (1) may further include a second contact portion. The second contact portion may be arranged on the second surface and connected to another end of the signal pattern in the first direction. The second dielectric layer may be arranged on the second surface to cover the signal pattern and expose the first contact portion and the second contact portion. The resin layer further may have a second side surface adjacent to the second contact portion in the first direction. The cloth may be located further inward than each of the first side surface and the second side surface in the first direction.

(3) The printed circuit board according to the above (1) or (2) may further include a second ground pattern arranged on the first surface.

(4) In the printed circuit board according to any one of the above (1) to (3), the reinforced fiber may be a glass fiber.

(5) In the printed circuit board according to any one of the above (1) to (4), the resin layer may be made of a fluororesin.

(6) A method of manufacturing a printed circuit board according to an embodiment includes preparing a first dielectric layer and a second dielectric layer. The first dielectric layer has a first surface and a second surface opposite to the first surface. A signal pattern is arranged on the second surface. The signal pattern extends in a first direction in plan view. A first contact portion is arranged on the second surface, and the first contact portion is connected to one end of the signal pattern in the first direction. The second dielectric layer has an adhesion layer and a resin layer. The resin layer has a third surface and a fourth surface opposite to the third surface, and the resin layer includes a cloth in which a reinforced fiber is woven. The adhesion layer is arranged on the third surface. A conductor layer is arranged on the fourth surface. The method of manufacturing the printed circuit board further includes affixing the second dielectric layer onto the second surface such that the adhesion layer covers the signal pattern and the first contact portion, forming a first ground pattern by patterning the conductor layer, and removing a first portion of the resin layer arranged on the first contact portion. A portion of the cloth located inside the first portion is separated in advance from a portion of the cloth located inside a second portion of the resin layer arranged on the signal pattern. According to the method of manufacturing a printed circuit board according to the above (6), the reinforced fiber is suppressed from becoming a burr on the side surface of the second dielectric layer.

### Details of Embodiments of Present Disclosure

The details of the embodiments of the present disclosure will be described with reference to the drawings. In the following drawings, the same or corresponding parts are denoted by the same reference numerals, and redundant description will not be repeated. A printed circuit board according to the embodiment is referred to as a printed circuit board 100.

### (Configuration of Printed Circuit Board 100)

The configuration of the printed circuit board 100 will be described below.

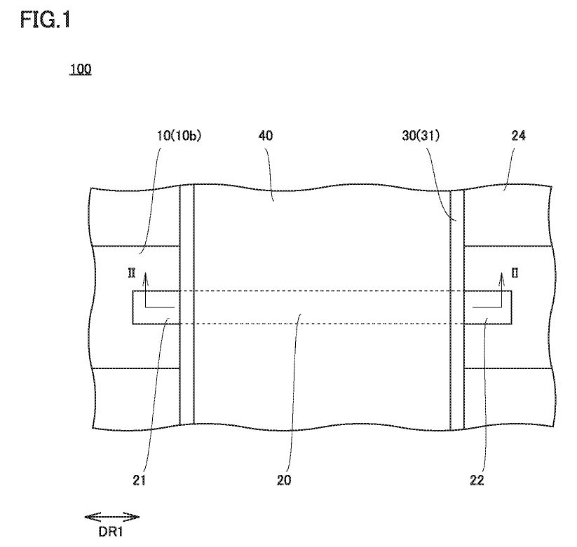

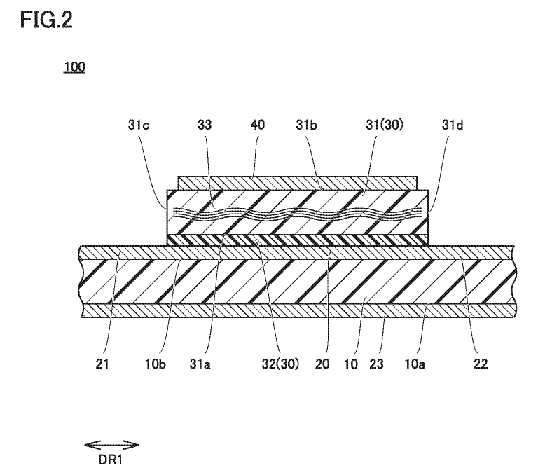

As shown in FIG. 1 and FIG. 2, the printed circuit board 100 includes a dielectric layer 10, a signal pattern 20, a contact portion 21, a contact portion 22, a ground pattern 23, a dielectric layer 30, and a ground pattern 40.

The dielectric layer 10 is made of a dielectric material. The dielectric layer 10 is made of, for example, a fluororesin. The dielectric layer 10 has a first surface 10a and a second surface 10b. The second surface 10b is a surface opposite to the first surface 10a. The first surface 10a and the second surface 10b are end surfaces of the dielectric layer 10 in the thickness direction.

The signal pattern 20 is made of a conductive material. The signal pattern 20 is made of, for example, copper or a copper alloy. The signal pattern 20 is arranged on the second surface 10b. The signal pattern 20 extends in a first direction DR1 in plan view (that is, when the printed circuit board 100 is viewed along the normal direction of the second surface 10b). For example, a high frequency signal flows through the signal pattern 20.

The contact portion 21 and the contact portion 22 are made of a conductive material. The contact portion 21 and the contact portion 22 are made of, for example, copper or a copper alloy. The contact portion 21 and the contact portion 22 are arranged on the second surface 10b. The contact portion 21 and the contact portion 22 are connected to both ends of the signal pattern 20 in the first direction DR1, respectively.

The ground pattern 23 is made of a conductive material. The ground pattern 23 is made of, for example, copper or a copper alloy. The ground pattern 23 is arranged on the first surface 10a. The printed circuit board 100 may further include a ground pattern 24. The ground pattern 24 is made of a conductive material, for example, copper or a copper alloy. The ground pattern 24 is arranged on the second surface 10b. The ground pattern 24 surrounds the signal pattern 20, the contact portion 21, and the contact portion 22 in the plan view. A ground potential is applied to the ground pattern 23 and the ground pattern 24.

The dielectric layer 30 includes a resin layer 31 and an adhesion layer 32. The resin layer 31 is made of a dielectric material. The resin layer 31 is made of, for example, fluororesin. The adhesion layer 32 is made of an adhesive.

The resin layer 31 has a third surface 31a and a fourth surface 31b. The fourth surface 31b is a surface opposite to the third surface 31a. The third surface 31a and the fourth surface 31b are end surfaces of the resin layer 31 in the thickness direction. The resin layer 31 has a side surface 31c and a side surface 31d. The side surface 31d is a surface opposite to the side surface 31c. The side surface 31c and the side surface 31d are end surfaces of the resin layer 31 in the first direction DR1. The side surface 31c is connected to the third surface 31a and the fourth surface 31b, and the side surface 31d is connected to the third surface 31a and the fourth surface 31b. The side surface 31c and the side surface 31d are adjacent to the contact portion 21 and the contact portion 22, respectively.

The adhesion layer 32 is arranged on the second surface 10b so as to cover the signal pattern 20. The resin layer 31 is arranged on the adhesion layer 32. In other words, the dielectric layer 30 covers the signal pattern 20 but does not cover the contact portion 21 and the contact portion 22. The third surface 31a faces the second surface 10b (the signal pattern 20) with the adhesion layer 32 interposed therebetween.

The resin layer 31 may include a cloth 33. The cloth 33 is arranged in the resin layer 31. The cloth 33 is formed by weaving a reinforced fiber into a cloth-like shape. The reinforced fiber is, for example, a glass fiber. That is, the cloth 33 is, for example, a glass cloth. The cloth 33 is located further inward than the side surface 31c and the side surface 31d in the first direction DR1. From another viewpoint, the cloth 33 is not exposed on the side surface 31c and the side surface 31d.

The ground pattern 40 is made of a conductive material. The ground pattern 40 is made of, for example, copper or a copper alloy. The ground pattern 40 is arranged on the resin layer 31 (on the fourth surface 31b). A ground potential is applied to the ground pattern 40. The signal pattern 20, the ground pattern 23, the ground pattern 40, the dielectric layer 10 arranged between the signal pattern 20 and the ground pattern 23, and the dielectric layer 30 arranged between the signal pattern 20 and the ground pattern 40 form a strip line structure.

### (Method of Manufacturing Printed Circuit Board 100)

Hereinafter, a method of manufacturing the printed circuit board 100 will be described.

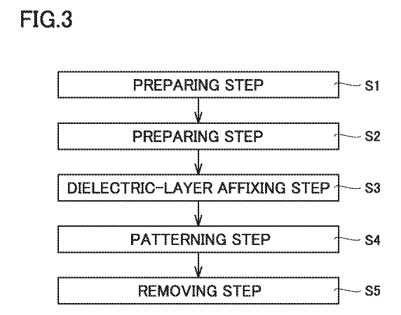

As shown in FIG. 3, the method of manufacturing the printed circuit board 100 includes a preparing step S1, a preparing step S2, a dielectric-layer affixing step S3, a patterning step S4, and a removing step S5.

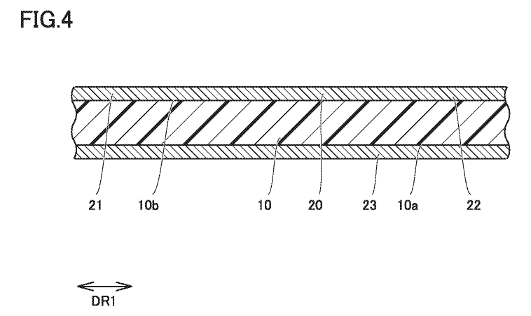

As shown in FIG. 4, in the preparing step S1, the dielectric layer 10 is prepared. In the dielectric layer 10 prepared in the preparing step S1, the ground pattern 23 is arranged on the first surface 10a, and the signal pattern 20, the contact portion 21, the contact portion 22, and the ground pattern 24 are arranged on the second surface 10b. It is noted that, the signal pattern 20, the contact portion 21, the contact portion 22, and the ground pattern 24 are formed by etching and patterning the copper layer arranged on the second surface 10b using a resist pattern. It is noted that, the resist pattern is formed by exposing and developing a dry film resist affixed on the copper layer.

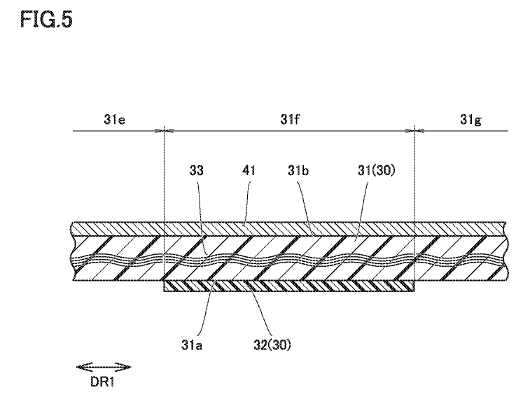

As shown in FIG. 5, in the preparing step S2, the dielectric layer 30 is prepared. In the dielectric layer 30 prepared in the preparing step S2, the adhesion layer 32 is arranged on the third surface 31a, and a copper layer 41 is arranged on the fourth surface 31b. However, at this stage, the adhesion layer 32 is uncured.

The resin layer 31 includes a first portion 31e, a second portion 31f, and a third portion 31g. The first portion 31e is a portion to be arranged on the contact portion 21 in a state in which the dielectric layer 30 is affixed. The second portion 31f is a portion to be arranged on the signal pattern 20 in a state in which the dielectric layer 30 is affixed. The third portion 31g is a portion to be arranged on the contact portion 22 in a state in which the dielectric layer 30 is affixed. The adhesion layer 32 is arranged on the third surface 31a located in the second portion 31f, but is not arranged on the third surface 31a located in the first portion 31e and the third surface 31a located in the third portion 31g.

Further, the portion of the cloth 33 located in the first portion 31e and the portion of the cloth 33 located in the third portion 31g are separated from the portion of the cloth 33 located in the second portion 31f. The resin layer 31 is formed by sandwiching the cloth 33 between two resin sheets each made of a fluororesin and hot-pressing the two resin sheets, for example. By partially cutting the cloth 33 before sandwiching the cloth 33 between the two resin sheets, the resin layer 31 is obtained in which the portion of the cloth 33 located in the first portion 31e and the portion of the cloth 33 located in the third portion 31g are separated from the portion of the cloth 33 located in the second portion 31f. The resin layer 31 may be prepared by other methods.

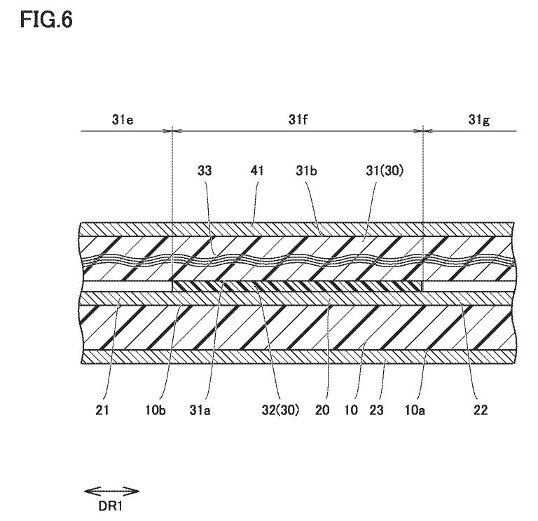

As shown in FIG. 6, in the dielectric-layer affixing step S3, the dielectric layer 30 is affixed to the dielectric layer 10. In the dielectric-layer affixing step S3, first, the dielectric layer 30 is arranged so that the adhesion layer 32 covers the signal pattern 20. Secondly, the dielectric layer 30 is hot-pressed against the dielectric layer 10. That is, the dielectric layer 30 is pressed toward the dielectric layer 10 while being heated. Thus, the adhesion layer 32 is cured, and the dielectric layer 30 is affixed to the dielectric layer 10 by the adhesion layer 32.

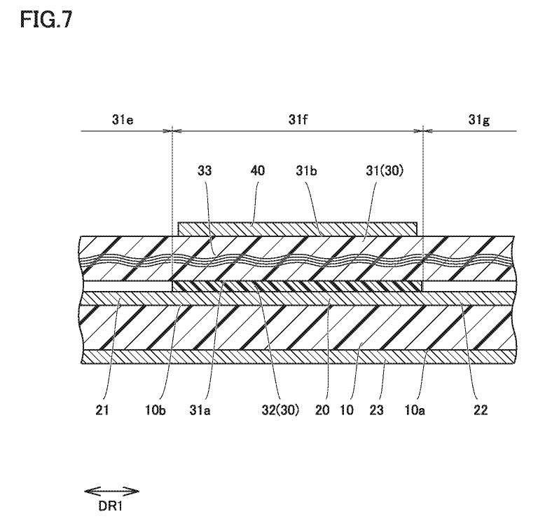

As shown in FIG. 7, in the patterning step S4, the copper layer 41 is patterned to form the ground pattern 40. In the patterning step S4, first, a resist pattern is formed on the copper layer 41. The resist pattern is formed by, for example, exposing and developing a dry film resist affixed on the copper layer 41. Secondly, the copper layer 41 is etched using the resist pattern as a mask, so that the copper layer 41 is patterned to form the ground pattern 40.

In the removing step S5, the first portion 31e and the third portion 31g are separated (peeled off), so that the dielectric layer 30 is removed from the contact portion 21 and the contact portion 22. Since the adhesion layer 32 is not arranged on the third surface 31a located in the first portion 31e and the third surface 31a located in the third portion 31g, the first portion 31e and the third portion 31g can be easily peeled off. As a result, the structure of the printed circuit board 100 shown in FIG. 1 and FIG. 2 is formed.

### Effects of Printed Circuit Board 100

Hereinafter, the effects of the printed circuit board 100 will be described in comparison with a printed circuit board according to a comparative example. The printed circuit board according to a first comparative example is referred to as a printed circuit board 200, and the printed circuit board according to a second comparative example is referred to as a printed circuit board 300.

A fluororesin has a low relative dielectric constant and is thus suitable as a material used for the resin layer 31. However, since the fluororesin has a large coefficient of thermal expansion, it is effective to arrange the cloth 33 in the resin layer 31 in order to reduce the coefficient of thermal expansion of the entire resin layer 31.

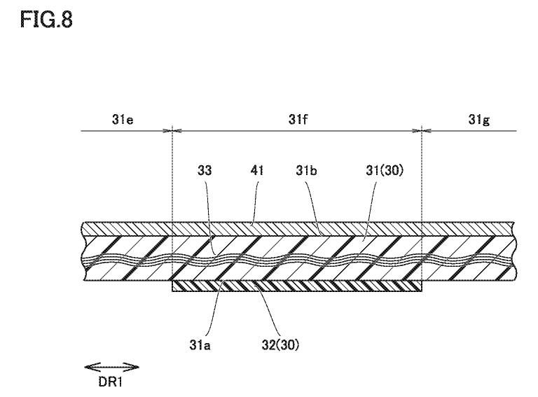

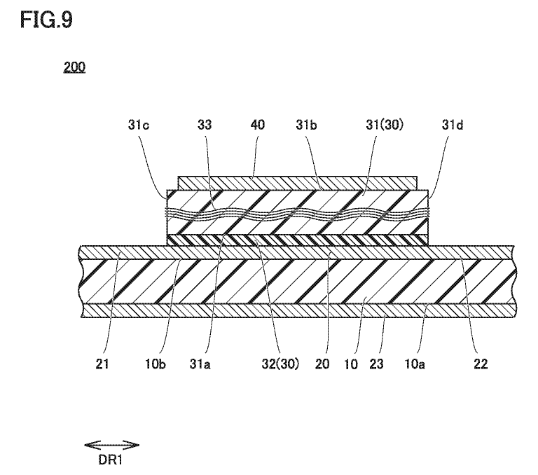

As shown in FIG. 8, in the dielectric layer 30 prepared in the manufacturing step of the printed circuit board 200, the portion of the cloth 33 located in the first portion 31e and the portion of the cloth 33 located in the third portion 31g are not separated from the portion of the cloth 33 located in the second portion 31f. Thus, as shown in FIG. 9, in the printed circuit board 200, the cloth 33 is exposed on the side surface 31c and the side surface 31d. Further, in the printed circuit board 200, the reinforced fiber of the cloth 33 cannot be torn off well when the first portion 31e and the third portion 31g are peeled off, and the reinforced fiber of the cloth 33 exposed on the side surface 31c and the side surface 31d may become a burr.

On the other hand, in the dielectric layer 30 prepared in the manufacturing step of the printed circuit board 100, the portion of the cloth 33 located in the first portion 31e and the portion of the cloth 33 located in the third portion 31g are separated in advance from the portion of the cloth 33 located in the second portion 31f. Thus, in the printed circuit board 100, the cloth 33 is located further inward than the side surface 31c and the side surface 31d, and the occurrence of the burr as described above is suppressed.

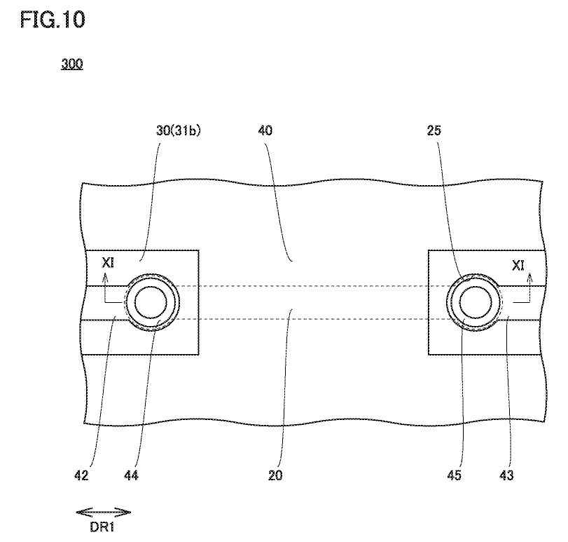

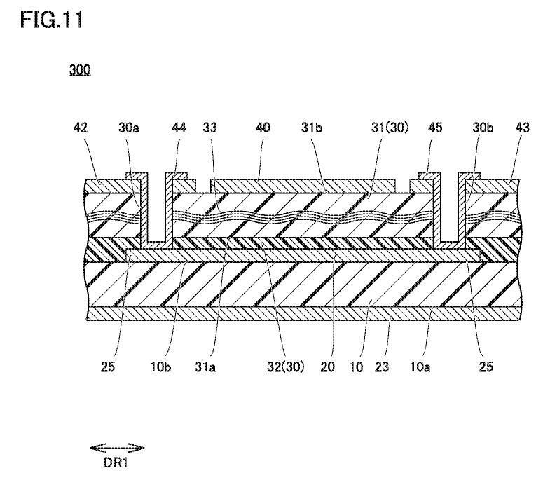

As shown in FIG. 10 and FIG. 11, the printed circuit board 300 does not have the contact portion 21 and the contact portion 22, but has annular rings 25 at both ends of the signal pattern 20. The printed circuit board 300 has a contact portion 42 and a contact portion 43. The contact portion 42 and the contact portion 43 are arranged on the dielectric layer 30 (on the fourth surface 31b). Further, in the printed circuit board 300, a through hole 30a exposing one end portion of the signal pattern 20 is formed in the dielectric layer 30 and the contact portion 42, and a through hole 30b exposing the other end portion of the signal pattern 20 is formed in the dielectric layer 30 and the contact portion 43.

Further, the printed circuit board 300 includes a conductor layer 44 and a conductor layer 45. The conductor layer 44 is arranged on the inner wall surface of the through hole 30a, on one end portion of the signal pattern 20 exposed from the through hole 30a, and on the contact portion 42 located around the through hole 30a, and electrically connects the contact portion 42 and the signal pattern 20. The conductor layer 45 is arranged on the inner wall surface of the through hole 30b, on the other end portion of the signal pattern 20 exposed from the through hole 30b, and on the contact portion 43 located around the through hole 30b, and electrically connects the contact portion 43 and the signal pattern 20.

When transmitting high-frequency signals, the strip line structure is more advantageous from the viewpoint of transmission characteristics. However, in the strip line structure, a signal pattern is arranged in an inner layer, and a contact portion arranged in an outer layer for external connection needs to be connected through a via hole. More specifically, in the printed circuit board 300, one end portion of the signal pattern 20 and the contact portion 42 need to be connected by the conductor layer 44, and the other end portion of the signal pattern 20 and the contact portion 43 need to be connected by the conductor layer 45. In order to prevent a connection failure due to a positional deviation, the annular rings 25 need to be formed at both ends of the signal pattern 20.

When the annular ring 25 is formed, impedance mismatching occurs between the conductor layer 44 and one end portion of the signal pattern 20 and between the conductor layer 45 and the other end portion of the signal pattern 20. The impedance mismatching portion becomes a reflection point of high-frequency signals, and transmission characteristics of high-frequency signals deteriorate. Further, in the printed circuit board 300, when high-frequency signals pass through the via hole, transmission loss also occurs.

On the other hand, in the printed circuit board 100, the first portion 31e and the third portion 31g are removed, and thus the contact portion 21 and the contact portion 22 are connected to the signal pattern 20 without via holes interposed therebetween, and thus transmission loss as in the printed circuit board 300 is less likely to occur. As described above, the printed circuit board 100 also improves the transmission characteristics of high-frequency signals.

### Modification

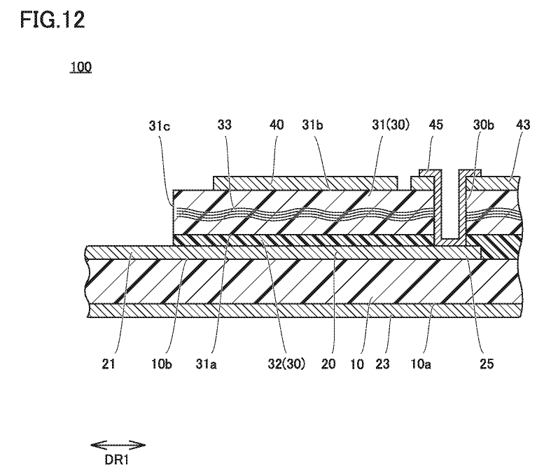

Although the example in which both the contact portion 21 and the contact portion 22 are exposed from the dielectric layer 30 has been described above, the configuration of the printed circuit board 100 is not limited thereto. For example, as shown in FIG. 12, the printed circuit board 100 may have the annular ring 25 connected to the other end of the signal pattern 20 instead of the contact portion 22. The dielectric layer 30 covers the annular ring 25. The printed circuit board 100 may further include the contact portion 43 and the conductor layer 45. That is, the printed circuit board 100 may have a contact portion connected to at least one of the one end portion and the other end portion of the signal pattern 20, the contact portion may be exposed from the dielectric layer 30, and the cloth 33 may be located inward from the side surface of the dielectric layer 30 adjacent to the contact portion in the first direction DR1.

The embodiments disclosed herein are to be considered in all respects as illustrative and not restrictive. The scope of the present invention is defined by the appended claims rather than the foregoing embodiments, and is intended to include any modifications within the scope and meaning equivalent to the appended claims.

What is claimed is:

1. A printed circuit board comprising:
a first dielectric layer;
a signal pattern;
a first contact portion;
a second dielectric layer; and
a first ground pattern,
wherein the first dielectric layer has a first surface and a second surface opposite to the first surface,
wherein the signal pattern is arranged on the second surface and extends in a first direction in plan view,
wherein the first contact portion is arranged on the second surface and connected to one end of the signal pattern in the first direction,
wherein the second dielectric layer is arranged on the second surface to cover the signal pattern and expose the first contact portion,
wherein the first ground pattern is arranged on the second dielectric layer,
wherein the second dielectric layer has an adhesion layer and a resin layer arranged on the adhesion layer and including a cloth in which a reinforced fiber is woven,
wherein the resin layer has a first side surface adjacent to the first contact portion in the first direction, and
wherein the cloth is located further inward than the first side surface in the first direction.

2. The printed circuit board according to claim 1, further comprising:
a second contact portion,
wherein the second contact portion is arranged on the second surface and connected to another end of the signal pattern in the first direction,
wherein the second dielectric layer is arranged on the second surface to cover the signal pattern and expose the first contact portion and the second contact portion,
wherein the resin layer further has a second side surface adjacent to the second contact portion in the first direction, and
wherein the cloth is located further inward than each of the first side surface and the second side surface in the first direction.

3. The printed circuit board according to claim 1, further comprising:
a second ground pattern arranged on the first surface.

4. The printed circuit board according to claim 1,
wherein the reinforced fiber is a glass fiber.

5. The printed circuit board according to claim 1,
wherein the resin layer is made of a fluororesin.

6. A method of manufacturing a printed circuit board, the method comprising:
preparing a first dielectric layer and a second dielectric layer,
the first dielectric layer having a first surface and a second surface opposite to the first surface,
a signal pattern being arranged on the second surface,
the signal pattern extending in a first direction in plan view,
a first contact portion being arranged on the second surface, the first contact portion being connected to one end of the signal pattern in the first direction,
the second dielectric layer having an adhesion layer and a resin layer,
the resin layer having a third surface and a fourth surface opposite to the third surface, the resin layer including a cloth in which a reinforced fiber is woven,
the adhesion layer being arranged on the third surface, and
a conductor layer being arranged on the fourth surface,
the method further comprising:
affixing the second dielectric layer onto the second surface such that the adhesion layer covers the signal pattern and the first contact portion;
forming a first ground pattern by patterning the conductor layer; and
removing a first portion of the resin layer arranged on the first contact portion,
wherein a portion of the cloth located inside the first portion is separated in advance from a portion of the cloth located inside a second portion of the resin layer arranged on the signal pattern.
